(19) United States
(12) Patent Application Publication
(10) Pub. No.: US 2026/0299006 A1
(43) Pub. Date: Oct. 1, 2026

(54) EVALUATION AND PERFORMANCE ANALYSIS OF DISCRETE FETS IN PARALLEL CONFIGURATIONS FOR POWER APPLICATIONS

(71) Applicant: Tektronix, Inc., Beaverton, OR (US)

(72) Inventors: Anshu BKY, Bengaluru (IN); Shubha B, Bengaluru (IN); Krishna N H Sri, Bengaluru (IN); Niranjan R Hegde, Bengaluru (IN); Vivek Shivaram, Bengaluru (IN); M. Venkatraj, Bengaluru (IN)

(21) Appl. No.: 19/578,571

(22) Filed: Mar. 25, 2026

(30) Foreign Application Priority Data
Mar. 28, 2025 (IN) 202521030186

(51) Int. Cl. G01R 31/27; G01R 31/26; G01R 31/265

(52) U.S. Cl. CPC G01R 31/275; G01R 31/2628; G01R 31/2642; G01R 31/265

(57) ABSTRACT

A test and measurement instrument includes two or more probes, each probe configured to be coupled to one field effect transistor (FET) of at least two paralleled FETs operating on a device under test (DUT) to receive signals from a same test point on each of the FETs, one or more analog-to-digital converters (ADCs) to convert the signals to waveforms for each paralleled FET; a display; and one or more processors configured to execute code that causes the one or more processors to: display the waveform for each of the at least two paralleled FET as overlapping waveforms; measure one or more performance characteristics of the at least two paralleled FETs; and identify optimal operating parameters of the at least two paralleled FETs based upon the overlapping waveforms.

### CROSS-REFERENCE TO RELATED APPLICATIONS

This disclosure claims priority under 35 U.S.C. § 119 to Indian Provisional Patent Application No. 202521030186, titled “EVALUATION AND PERFORMANCE ANALYSIS OF DISCRETE FETS IN PARALLEL CONFIGURATIONS FOR POWER APPLICATIONS,” filed on Mar. 28, 2025, the disclosure of which is incorporated herein by reference in its entirety.

### TECHNICAL FIELD

The present disclosure relates to power electronics and semiconductor devices, specifically focusing on paralleling MOSFETs (metal oxide semiconductor field effect transistor) in high-power applications.

### BACKGROUND

As the demand for paralleling MOSFETs in high-power converter applications increases, design engineers face a significant challenge in achieving balanced current sharing and power dissipation among parallel MOSFETs. This issue arises because MOSFETs are not perfectly synchronized during turn-on and turn-off transitions.

While paralleling MOSFETs is essential for efficiently handling high currents, it poses challenges such as unequal current distribution, thermal imbalances, and increased switching losses. These challenges can result in overheating, reliability issues, and reduced system efficiency.

When multiple FETs are used in parallel to handle higher currents, differences in their electrical characteristics can lead to uneven current distribution.

To achieve higher current ratings with MOSFETs there are some significant advantages to paralleling lower current modules, especially PCB based devices. This is because the traditional higher rated current packages were not designed with silicon carbide (SiC) MOSFETs in mind, and where simple two screw terminals alone can add up to tens of nanoHenrys (nH) to a power inductance loop. In contrast, PCB based packages can achieve very low inductances with physically small power loop areas and utilize the potential of laminated structures offered by multi-layer PCBs. This coupled with the ability to have low and equal gate inductances and very symmetrical internal chip layouts allows faster switching speeds to be achieved.

Electrification, digitization, and renewables need these kinds of topologies to achieve high power applications.

Prior solutions are often tailored to specific configurations such as Vth, resistance between the drain and the source RDSₒₙ, etc., which can limit their scalability. Many of these approaches depend on static measurements or post-processing analyses, potentially overlooking transient issues that occur during dynamic operations. One common method, known as MOSFET binning, involves selecting closely matched MOSFETs based mostly on parameters like threshold voltage Vth and on-resistance RDSₒₙ. However, this technique does not always guarantee uniform current sharing among the devices. Additionally, while incorporating individual gate resistors is a strategy aimed at balancing switching speeds and minimizing mismatches, it may not fully achieve these objectives. Proper selection and optimization of gate resistor values is crucial for effective current sharing and to prevent issues such as gate oscillations.

Paralleling power MOSFETs introduces several challenges that must be addressed to ensure the optimal performance and reliability. Even though the positive temperature coefficient inherent in MOSFETs can counter thermal runaway in parallel configurations, it can still be caused by uneven Vth or RDSon, leading to device failure.

Ensuring synchronized gate drive signals is also crucial; any variations can cause discrepancies in switching times, resulting in imbalanced current sharing among the devices.

Additionally, mismatch in dynamic on-resistance RDSon can lead to uneven current distribution, as each device may carry different current levels. During rapid switching events, differences in switching speeds and parasitic elements can exacerbate transient current sharing issues.

Moreover, conventional test and measurement vendors lack dedicated software methods to compute dynamic RDSon, and this complicates accurate analysis and measurement of current sharing in parallel device configurations, highlighting the need for advanced solutions in this area.

Currently, to mitigate these challenges, designs are increasingly adopting symmetric PCB layouts. These layouts try to reduce parasitic effects and balance current distribution among parallel MOSFETs by ensuring identical trace lengths and low-inductance paths. Active current balancing circuits offer another solution by dynamically adjusting current distribution among MOSFETs using external feedback mechanisms. These circuits enhance performance but do not completely prevent imbalances that can lead to device stress or failure.

### BRIEF DESCRIPTION OF THE DRAWINGS

FIG. 1 shows a current example of paralleling two MOSFETs.

FIG. 2 shows non-uniform distribution of output currents between FETs.

FIG. 3 shows an example of overlapped reverse recovery body diode currents waveforms for parallel FETs.

FIG. 4 shows an embodiment of a testing configuration for device under test (DUT) with paralleled FETs.

FIG. 5 shows a flow chart of an embodiment of a RDSon measurement for paralleled FETs.

FIG. 6 shows a flow chart of an embodiment of an Eₒₙ measurement for paralleled FETs.

FIG. 7A shows an example of a plot of drain currents and Vds voltages for two paralleled FETs.

FIG. 7B shows an example of a plot of a zoomed in version of drain currents sharing between left and right load outputs for paralleled FETs.

FIG. 8 shows an example of a plot of on resistance indicating current imbalance between paralleled FETs.

FIG. 9 shows an example of a plot of overlapped waveforms.

FIG. 10 shows a display of overlapped waveforms showing leakage current.

FIG. 11 shows an embodiment of a user interface to allow a use to configure an inductance measurement during a double-pulse test.

FIG. 12 shows an example of overlapped waveforms for paralleled FETs during switching transitions.

FIGS. 13A and 13B show examples of waveform having damping factor transient responses for voltage and current, respectively.

FIG. 14 shows an example of overlapped waveforms demonstrating the peaks in drain currents and the gate-source voltage showing the effects of a damping factor.

FIGS. 15A-15B shows examples of overlapped waveforms demonstrating overshoot for voltage and current, respectively.

FIGS. 16A-16B shows examples of overlapped waveforms demonstrating undershoot for voltage and current, respectively.

### DETAILED DESCRIPTION

The embodiments disclosed herein involve an approach that includes real-time monitoring of individual MOSFET (metal oxide semiconductor field-effect transistors) currents through oscilloscope-based or integrated sensing techniques, providing immediate visualization of current sharing dynamics.

By analyzing both current and voltage waveforms, it is possible to pinpoint the root causes of current sharing issues, whether they stem from RDSₒₙ mismatches, threshold voltage (Vth) variations, gate resistance discrepancies, or parasitic inductances etc.

Furthermore, the methods of the embodiments scale for high-power applications and are compatible with silicon (Si), silicon carbide (SiC), and gallium nitride (GaN) power devices across automotive, industrial, and data center sectors. Some industry use cases indicate that users have paralleled up to twelve MOSFETs. The solution provided in this subject patent application provides for these instances with multi-scope sync feature.

Collectively, these innovations offer a comprehensive solution to the challenges associated with paralleling power MOSFETs, enhancing the reliability and efficiency of power electronic systems.

The discussion uses several terms related to performance characteristics of MOSFETs. The term “performance characteristic” as used here means various currents and voltages that describe the environment in which MOSFETS operate, as well as those that result from operation of the MOSFETs. These include drain current (Id), gate-source volage (Vgs), drain-source voltage (Vds), threshold voltage (Vth), and others. The term “operating parameter” as used here means those parameters that are controllable, such as input current (Iᵢₙ), gate voltage, power (Vcc and Vdd), and others.

Most of the embodiments discussed herein involve paralleling two MOSFETs, with the understanding that the embodiments apply to larger numbers of paralleled MOSFETs. The discussion here, and the figures, refer to the two MOSFETs as MOSFET1 and MOSFET2, Q1 and Q2, and the various measures may be referred to with a number to identify from which MOSFET that measurement was taken. For example, Id1, refers to the drain current in MOSFET1/Q1.

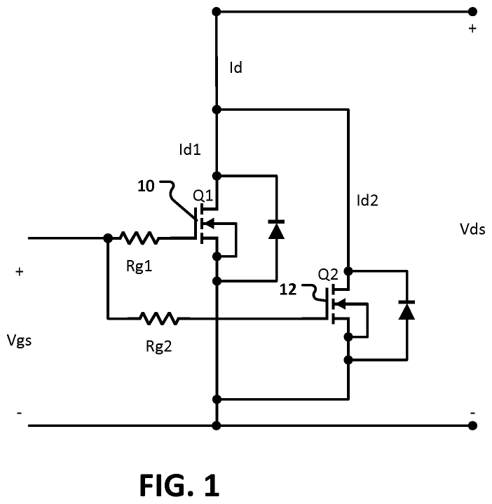

FIG. 1 shows an example of two paralleled MOSFETs 10 and 12. Paralleling power MOSFETs is a common way to reduce conduction losses and spread power dissipation over multiple devices to limit the maximum junction temperature. Id gets split into two parts, and the load on both MOSFETs is divided.

In the parallel designs, it is important to reduce any currents flowing in the auxiliary source connection. In paralleling MOSFETs, the auxiliary source connection, also referred to as the Kelvin source, typically comprises a dedicated pin or bond wire that provides a separate return path for the gate driver current. This is normally distinct from the main power source.

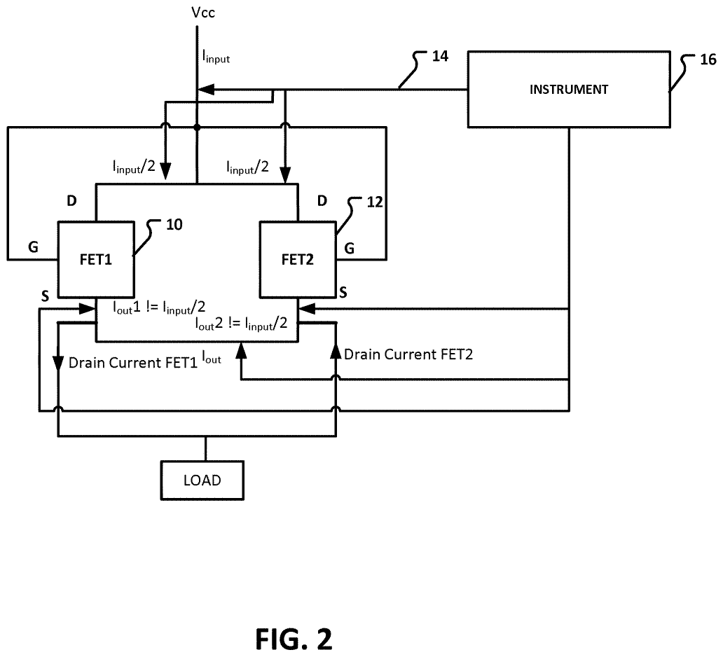

FIG. 2 shows how non-uniform distribution of output currents can occur between FETs 10 and 12 due to different operating characteristics of the FETs. This current variation can cause gate oscillations and even be large enough to cause the module internal bond wires to open as a fuse. As discussed below, the variation between FETs in the on-resistance (RDSₒₙ) and other characteristics provides inherent negative feedback during static sharing.

If one MOSFET conducts more current and consequently heats up, its increased RDSₒₙ reduces the current it carries, thereby mitigating the risk of thermal runaway. However, this self-balancing effect is not absolute. Variations in RDSon among devices can lead to uneven current distribution, as the MOSFET with the lowest RDSon naturally conducts more current. As it heats up and its RDSon rises, some current is redistributed to other parallel devices. This results in the Iout1 and Iout2 being different than what was desired, as shown.

Nonetheless, achieving precise current sharing depends on the relative on-resistance of each MOSFET and their respective temperature coefficients. Moreover, an increase in dynamic RDSₒₙ can result in higher conduction losses and reduced efficiency, particularly in high-frequency applications utilizing GaN and SiC devices where switching losses are critical.

It is also important to note that while RDSₒₙ mismatch significantly affects steady-state current sharing, its impact on transient current sharing is minimal,

The embodiments disclosed herein provide analysis of dynamic on-resistance RDSₒₙ in parallel FETs. In general, SiC and GaN FETs exhibit a positive temperature coefficient (PTC) for their on-resistance RDSₒₙ when compared to the Vcesat characteristic of a silicon IGBT (insulated gate bipolar transistor), meaning that as the device heats up, RDSₒₙ increases.

Therefore, dynamic RDSₒₙ measurement across different temperatures is essential to ensure balanced performance and prevent thermal issues in parallel MOSFET configurations.

In an embodiment, analyzing overlapped current and voltage plots is essential for understanding the performance and reliability of parallel MOSFET configurations. The embodiments here include a test and measurement instrument 16 that gathers waveforms from both/all paralleled FETs using probes such as 14 and displays overlapped current plots. By superimposing the turn-on and turn-off current waveforms of parallel MOSFETs, it allows detection of current imbalances, timing discrepancies, and current-sharing behavior during transitions. This approach aids in identifying turn-on/off imbalances, measuring current delay effects, and assessing switching loss distribution within the system.

The overlapped current plots allow for detection of several different issues. These include current imbalance. If one of the MOSFETs conducts more current, it indicates a mismatch in parameters such as dynamic RDSₒₙ. The device with the lowest RDSₒₙ typically carries more current, with the understanding that thermal effects may balance this over time. Another issue may arise from turn-on delay. Discrepancies in the rise times of current waveforms suggest unsynchronized drive timing. Similarly, Turn-off delay may result in variations in fall times indicate that some MOSFETs turn off later, leading to unbalanced switching losses. Another issue detectable from the overlapped current plots is total current distortion in which an irregular total current waveform implies unequal contributions from the MOSFETs.

Superimposing the drain-source voltage (Vds) waveforms of parallel MOSFETs reveals insights into switching behavior, including voltage imbalances, and the influence of circuit parasitics. This analysis is crucial for detecting timing mismatches, identifying voltage stress, and assessing the impact of parasitic inductances and capacitances. The following issues become detectable. One issue involves timing mismatches. If Vds waveforms transition at different times, it indicates mismatches in gate drive timing or threshold voltage (Vth) variations. Voltage stress is now detectable because differences in peak voltage levels during switching transitions suggest variations in parasitic inductances or capacitances, which can lead to some MOSFETs experiencing higher voltage stress, potentially exceeding their safe operating area (SOA). Further, one can now detect parasitic effects which may cause variations in ringing frequency or amplitude after switching transitions indicate differences in resonant frequencies determined by parasitic elements.

Therefore, it is apparent that careful examination of overlapped current and voltage plots is vital for diagnosing and mitigating issues in parallel MOSFET designs, ensuring balanced operation, and enhancing overall system performance.

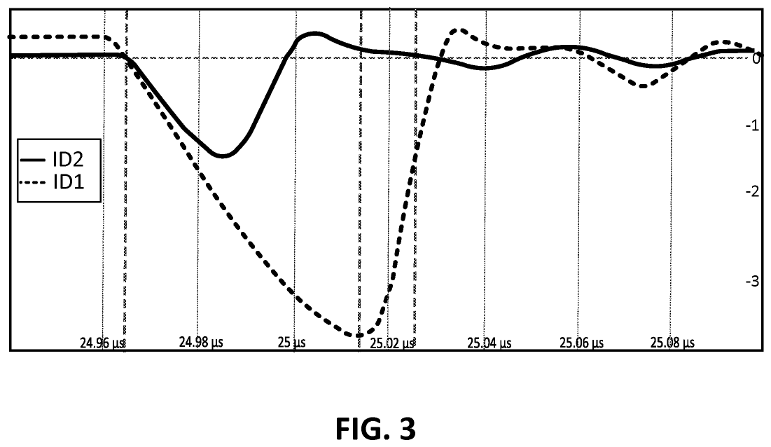

In an embodiment, the body diode current analysis can be performed using the plots shown in FIG. 3. FIG. 3 shows double-pulse test (DPT) turn-off waveforms for two high-side paralleled FETs Q1 and Q2. The waveforms illustrate the actual results from overlapped reverse recovery body diode freewheeling currents. Reverse recovery occurs when a diode transitions from conducting in the forward direction to blocking in the reverse direction, during which a reverse current flows as the diode recovers. In parallel FET configurations, analyzing these overlapped body diode currents/reverse recovery currents in power MOSFETs is crucial for ensuring efficient and reliable circuit operation. The body diode's reverse recovery time, meaning the period during which the diode continues to conduct in reverse direction after switching, can lead to significant power losses and voltage spikes if not properly managed.

By examining these overlapping current waveforms, engineers can detect timing mismatches, current imbalances, assess switching losses or device stress, and design appropriate snubber circuits to mitigate adverse effects, thereby enhancing overall system performance.

Several methods for parallel current-sharing analysis are outlined and briefly explained below. One method involves cross-correlation-based fault detection in parallel MOSFETs.

Traditional current-sharing measures primarily focus on average current distribution, often failing to detect early-stage failures in parallel-connected power devices. This limitation poses a significant challenge in high-power converters, where undetected faults can lead to catastrophic failures. Conventional methods overlook crucial indicators such as subtle waveform shifts and phase delays, which can serve as early warning signs of impending device degradation. To address this issue, a cross-correlation-based fault detection technique can be implemented to analyze waveform mismatches in parallel power devices.

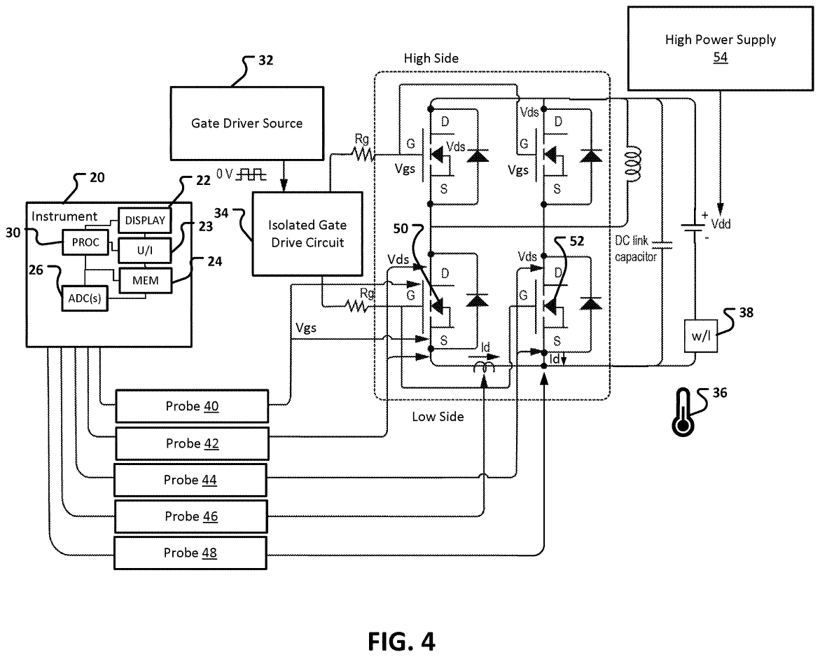

By utilizing a test and measurement instrument such as an oscilloscope, early signs of gate degradation, threshold voltage (Vth) drift, and thermal runaway can be detected before complete failure occurs. Real-time monitoring, combined with FPGA-based computation, enables efficient data processing and the need for activation of protection mechanisms, thereby enhancing system reliability. As will be discussed in more detail below, with regard to FIG. 4, the test and measurement instrument includes one or more processing elements, referred to here as a processor, that can perform these analyses. The term “one or more processors” as used here includes any FPGAs or other processing elements that are in the test and measurement instrument.

Another method involves AI-driven dynamic gate drive tuning for parallel power devices. In parallel MOSFETs, IGBTs, and GaN transistors, current sharing is often compromised due to fixed gate drive configurations. This leads to mismatched switching times and increased power losses. Variations in threshold voltage (Vth), drain-to-source resistance (RDSₒₙ), and stray inductance result in uneven current distribution, which can accelerate device failure, elevate thermal stress, and reduce overall efficiency.

Traditional gate drive methodologies lack adaptability, making them insufficient for addressing dynamic variations in power devices. To overcome these challenges, an AI-driven real-time gate drive tuning system can be employed. This system continuously adapts gate drive parameters based on gate-to-source voltage (Vgs), drain current (Id), and switching losses. By leveraging machine learning models trained on previous drive parameters and the factors above to predict optimal gate drive configurations to compensate for device variations, thereby enhancing power conversion efficiency and improving system reliability.

AI may also be employed in other ways. In an embodiment, AI can be used when paralleling GaN with SiC for hybrid current sharing in high-power inverters. GaN transistors offer superior efficiency at high switching speeds, while SiC devices excel in handling high voltages. However, combining these technologies in a parallel operation poses challenges due to their distinct electrical characteristics. The AI-based adaptive gate drive tuning system can be implemented to align their switching behaviors, ensuring optimal current sharing and improved overall system efficiency.

In another embodiment the test and measurement instrument can employ wireless real-time current balancing in parallel SiC/GaN. Traditional wired current-sensing methods introduce stray inductance and noise, impacting the accuracy of measurements in high-frequency applications. With high-power SiC and GaN transistors increasingly replacing traditional silicon MOSFETs, precise current sharing has become critical due to their low ON-resistance and high-speed switching characteristics. Existing wired current sensing techniques, typically using wired probes, introduce parasitic inductance, delays, and noise, rendering them unsuitable for high-speed applications. To address this, a wireless real-time current monitoring solution can implement a feedback control loop that dynamically adjusts gate signals which can enhance current balancing and mitigate power losses in parallel power devices. Wireless real-time current monitoring would replace the probes seen in FIG. 2 and those that will be discussed with regard to FIG. 4.

In another embodiment, the test and measurement instrument can provide thermal-driven adaptive current sharing in parallel SiC/GaN devices. Uneven thermal distribution in parallel MOSFETs or SiC transistors can result in thermal runaway, significantly reducing device lifespan and reliability. To counteract this issue, on-chip thermal sensors can be integrated to monitor temperature differences in real-time, enabling adaptive current sharing mechanisms that optimize power device performance and longevity.

In another embodiment, one could employ self-powered current sharing monitors for high-power parallel transistors. Current-sharing monitoring systems often rely on external power sources, making on-board monitoring complex, particularly in remote applications. To address this limitation, a self-powered current sensor can be designed to harvest energy from switching transients. Additionally, a low-power wireless communication system can be integrated to transmit real-time current-sharing data, facilitating efficient and autonomous system monitoring. This allows the wireless current monitors, whether self-powered or not, to communicate with the test and measurement instrument.

FIG. 4 shows an embodiment of a test and measurement instrument set up for a half-bridge device under test (DUT). One should note that the setup includes a test and measurement instrument, as well as several different types of sensors. These apply across all embodiments, not limited to the DUT discussed in FIG. 4.

The embodiment of FIG. 4 contains a half bridge MOSFET DUT with paralleling High Electron Mobility Transistors (HEMTs). The board features four gallium nitride (GaN) power transistors, a pair of compact gate drivers, along with input logic that provides adjustable dead-time. The setup involves a signal generator used as a gate driver source 32, a voltage generator used as a high power supply 54 and a test and measurement instrument 20. The test and measurement instrument 20 may have many components not specifically discussed here. The instrument 20 includes a display 22, upon which the overlapped waveforms are displayed. The user interface 23 allows the user to make inputs to the instrument to perform different types of tests and to identify the desired display. A memory 24 may comprise more than one memory. Memory 24 may include an acquisition memory that stores the waveform data converted from the various probes that are coupled to the DUT. The analog-to-digital converter(s) (ADC) 26 receive the signals from the DUT through the probes and convert them into the waveform data that will ultimately be displayed on the display. The processor 30 may comprise one or more of many different types of processing elements, including but not limited to one or more general-purpose processors, digital signal processors, field programmable gate arrays (FPGA), microcontrollers, application specific integrated circuits, etc., or a mix of any or all of those.

The one or more processors represented by processor 30 are configured to execute code that may be stored in the memory, to operate the instrument 20 to perform the methods and processes of the embodiments. The one or more processors may interact with the gate drive circuit 34 by control of the gate drive source 32, which in turn interacts with the gate drive circuit 34. The code may include code that causes the one or more processors to perform calculations and other processes and may operate the code that represents the AI models mentioned above. The probes shown here may be replaced by wireless current monitors, such as 38 that may be self-powered as discussed above, and additional probes or current monitoring sensors may gather data from thermal sensors such as 36, as mentioned above.

In one configuration, for ease of understating, probes 46 and 48 are used to monitor drain currents. For Vgs, probe 40 may be used. To measure Vds, probes 42 and 44 are used. Probe settings like attenuation and bandwidths are matched. Deskew is done to all probes with respect to Vgs. The instrument 20 uses the proposed wide-band gap (WBG) parallel analysis solution to measure various parameters of the low-side paralleled MOSFETs 50 and 52 to analyze the performance of the parallel configuration of current shared MOSFETs.

For the parallel MOSFETS, many measurements are run to compare the performance of parallel operation. This include on-state current, transient current, current overshoot, switching loss, turn-on loss, turn-off loss, turn-on delay, in which currents rising at different times means that the drive timing is not synchronized, turn-on delay, where some MOSFETs turning off later leads to unbalanced switching losses, total current distortion, where if the Iₜₒₜₐₗ waveform is not smooth, MOSFETs are not equally contributing. Further measurements may include drain-source voltage, transients including, software speeds, overshoot and undershoot, stray inductances, phase synchronization or difference between FETs, and body diode (high-side) current monitoring.

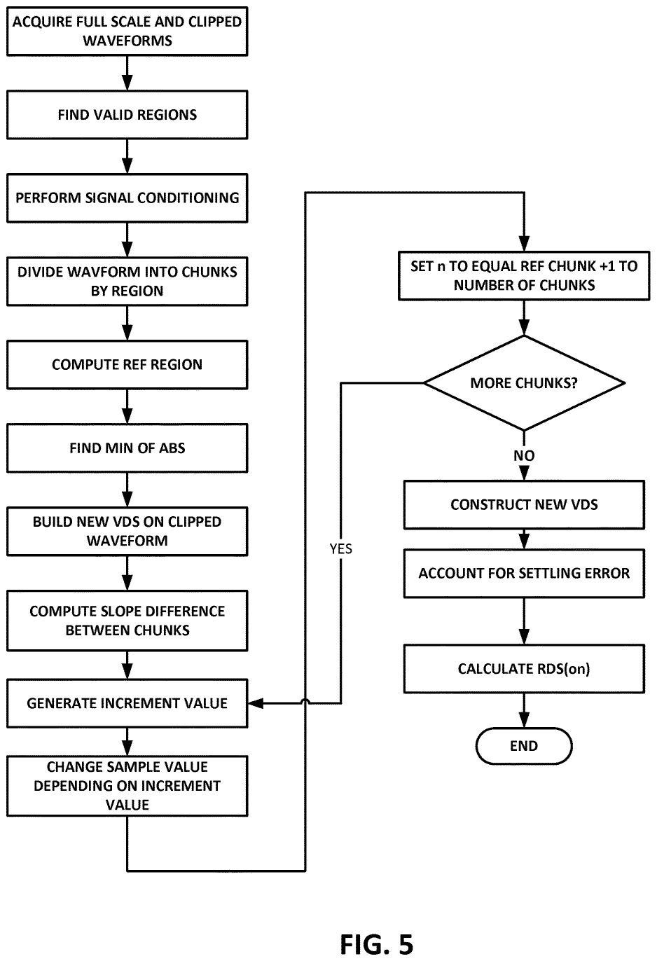

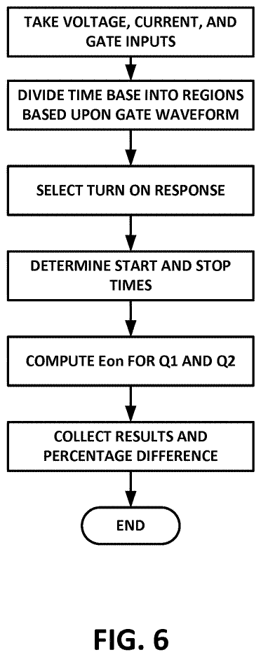

FIG. 5 shows a flowchart of an embodiment showing the measurement of RDSon and FIG. 6 shows a flowchart of an embodiment of a parallel Eon measurement. These demonstrate how the information gathered by the test and measurement instrument can make measurements usable in altering operation of the paralleled FETs.

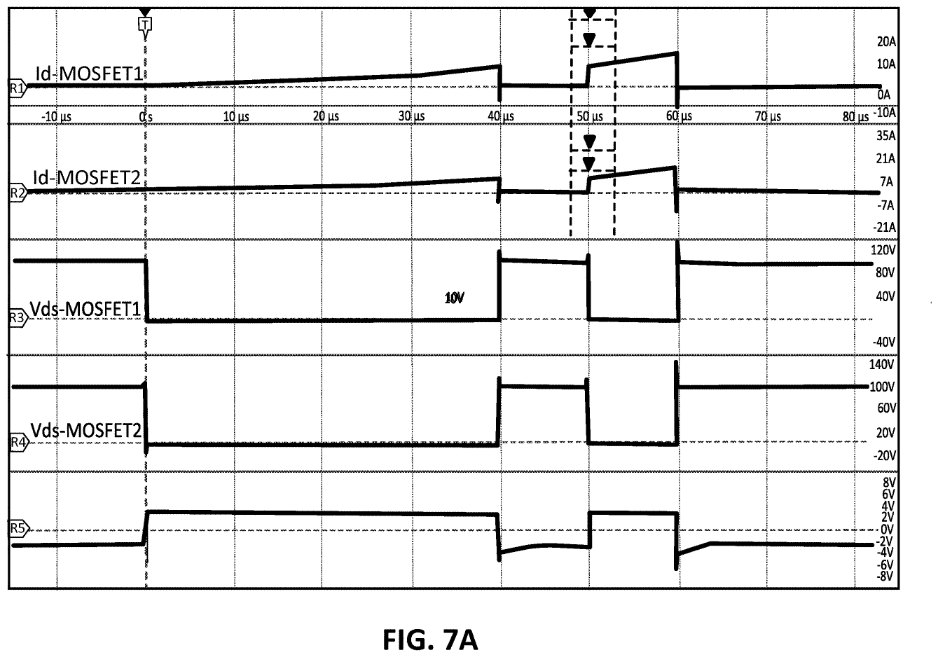

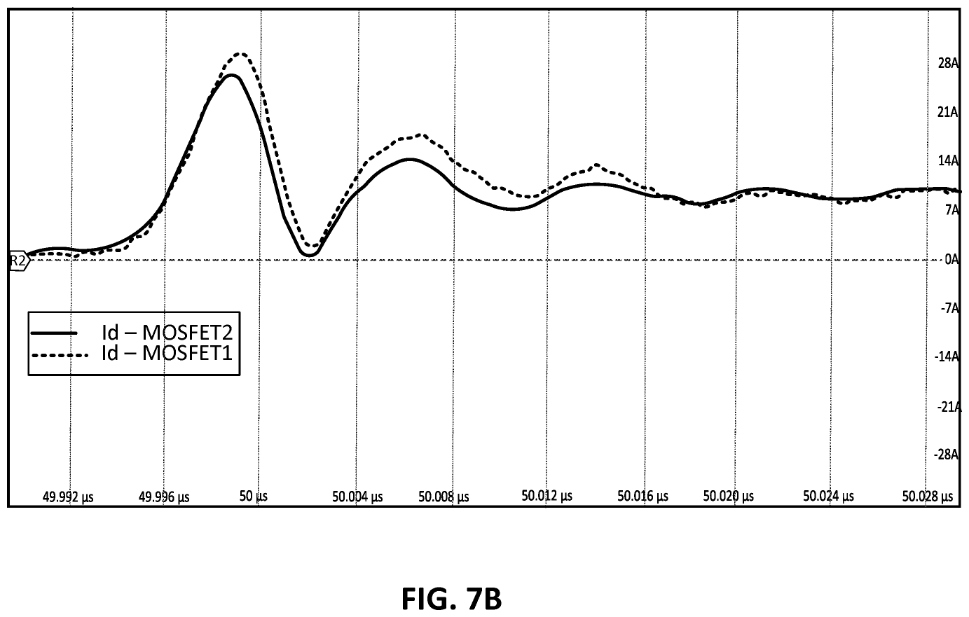

FIG. 7A shows a display of drain currents and Vds voltages and FIG. 7B shows a zoomed-in view of drain currents sharing between left and right load outputs.

The following table summarizes an example Parallel MOSFET Performance Comparison Matrix. It describes the key performance metrics extracted from testing the half bridge GAN evaluation board. Parameters such as Eon, Eoff etc., were measured to assess current sharing performance between the parallel GaN HEMTs.

| | | off | | turn on | | ON | | turn off | | off | |
|---|---|---|---|---|---|---|---|---|---|---|---|
| Region | Col 1 | region1 | | transition 1 | | region 1 | | transition 1 | | region2 | |
| Eon | Device 1 | | | 614.867 | nJ | | | | | | |
| | Device 2 | | | 648.072 | nJ | | | | | | |
| | Difference | | | 33.205 | nJ | | | | | | |
| Eoff | Device 1 | | | | | | | 405.336 | nJ | | |
| | Device 2 | | | | | | | 407.347 | nJ | | |
| | Difference | | | | | | | 2.011 | nJ | | |
| Voltage | Device 1 | | | | | | | 10.371 | V | | |
| overshoot | Device 2 | | | | | | | 10.525 | V | | |
| | Difference | | | | | | | 0.154 | V | | |
| Voltage | Device1 | | | | | | | 34.558% | | | |
| Overshoot | Device2 | | | | | | | 35.391% | | | |
| (%) | Difference | | | | | | | 0.838% | | | |
| voltage | Device1 | | | 35.14% | | | | | | | |
| undershoot(%) | Device2 | | | 43.20% | | | | | | | |
| | Difference | | | 8.06% | | | | | | | |
| current | Device 1 | | | 8.935 | A | | | | | | |
| overshoot | | | | | | | | | | | |
| | Device 2 | | | 8.831 | A | | | | | | |
| | Difference | | | 0.104 | A | | | | | | |
| current | Device 1 | | | | | | | 3.264 | A | | |
| undershoot | Device 2 | | | | | | | 3.065 | A | | |
| | Difference | | | | | | | 0.199 | A | | |
| leakage | Device 1 | 517.216 | mA | | | | | | | 543.886 | mA |
| current | Device 2 | 472.399 | mA | | | | | | | 484.656 | mA |
| | Difference | 44.817 | mA | | | | | | | 59.230 | mA |
| current | Device 1 | | | | | 2.223 | A | | | | |
| sharing | Device 2 | | | | | 2.196 | A | | | | |
| | Difference | | | | | 0.027 | A | | | | |
| Vds | Device 1 | | | | | | | 8.040 | m | | |
| Damping | Device 2 | | | | | | | 0 | | | |
| Factor | Difference | | | | | | | 8.04 | m | | |

| | | turn on | | on | | turn off | | off | |
|---|---|---|---|---|---|---|---|---|---|
| Region | Col 1 | transition2 | | region 2 | | transition 2 | | region3 | |
| Eon | Device 1 | 1.078 | uJ | | | | | | |
| | Device 2 | 1.214 | uJ | | | | | | |
| | Difference | 0.136 | uJ | | | | | | |
| Eoff | Device 1 | | | | | 377.574 | nJ | | |
| | Device 2 | | | | | 356.015 | nJ | | |
| | Difference | | | | | 21.559 | nJ | | |
| Voltage | Device 1 | | | | | 20 | V | | |
| overshoot | Device 2 | | | | | 22.8 | V | | |
| | Difference | | | | | 2.8 | V | | |
| Voltage | Device1 | | | | | 66.95% | | | |
| Overshoot | Device2 | | | | | 76.29% | | | |
| (%) | Difference | | | | | 9.34% | | | |
| voltage | Device1 | 32.47% | | | | | | | |
| undershoot(%) | Device2 | 43.20% | | | | | | | |
| | Difference | 10.73% | | | | | | | |
| current | Device 1 | 11.928 | A | | | | | | |
| overshoot | | | | | | | | | |
| | Device 2 | 10.744 | A | | | | | | |
| | Difference | 1.184 | A | | | | | | |
| current | Device 1 | | | | | 5.573 | A | | |
| undershoot | Device 2 | | | | | 5.318 | A | | |
| | Difference | | | | | 0.455 | A | | |
| leakage | Device 1 | | | | | | | 536.569 | mA |
| current | Device 2 | | | | | | | 480.995 | mA |
| | Difference | | | | | | | 55.574 | mA |
| current | Device 1 | | | 4.662 | A | | | | |
| sharing | Device 2 | | | 4.629 | A | | | | |
| | Difference | | | 0.033 | A | | | | |
| Vds | Device 1 | | | | | 20.255 | m | | |
| Damping | Device 2 | | | | | 22.027 | m | | |
| Factor | Difference | | | | | 1.772 | m | | |

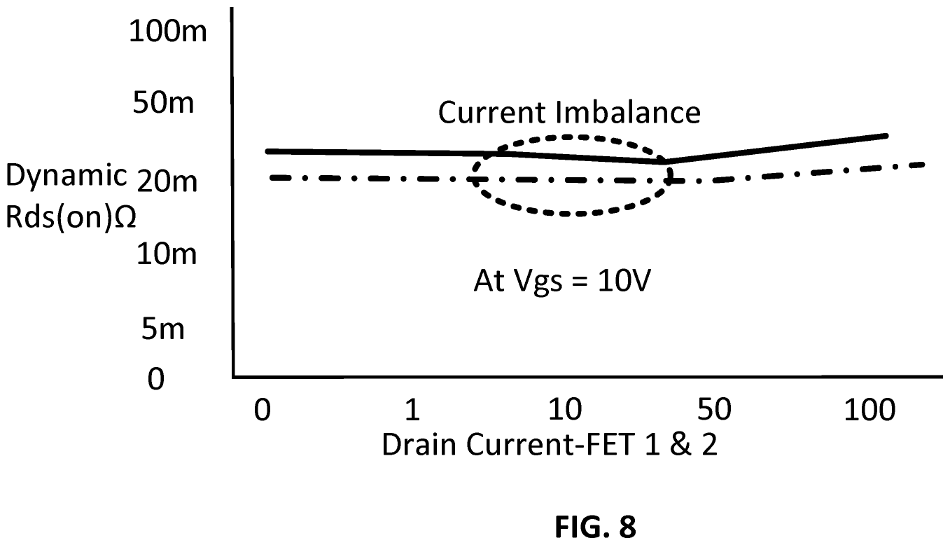

FIG. 8 illustrates the a plot of on resistance indicating current imbalance between FETs. The graph shows the characteristics of how the RDSₒₙ value responds to drain current. Since the test pulse time is short enough to not affect the junction temperature, most characteristics are expected to have consistent RDSₒₙ values. If there is a variation in RDSₒₙ between FETs that is due to current imbalance, that is shown by the dashed circle.

Another measurement that can be run is transconductance. Transconductance quantifies how much the drain current (Id) changes for a small change in gate-source voltage (Vgs), at a constant drain-source voltage (Vds). It also computes the difference in transconductance between the two devices to assess matching. It is measured with drain-source voltage Vds held constant. Higher transconductance means stronger gate control and faster device switching. The fundamental transconductance formula is transconductance=dId/dVgs (Siemens or A/V), wherein dId is the change in drain current, and dVgs is the change in gate-source voltage.

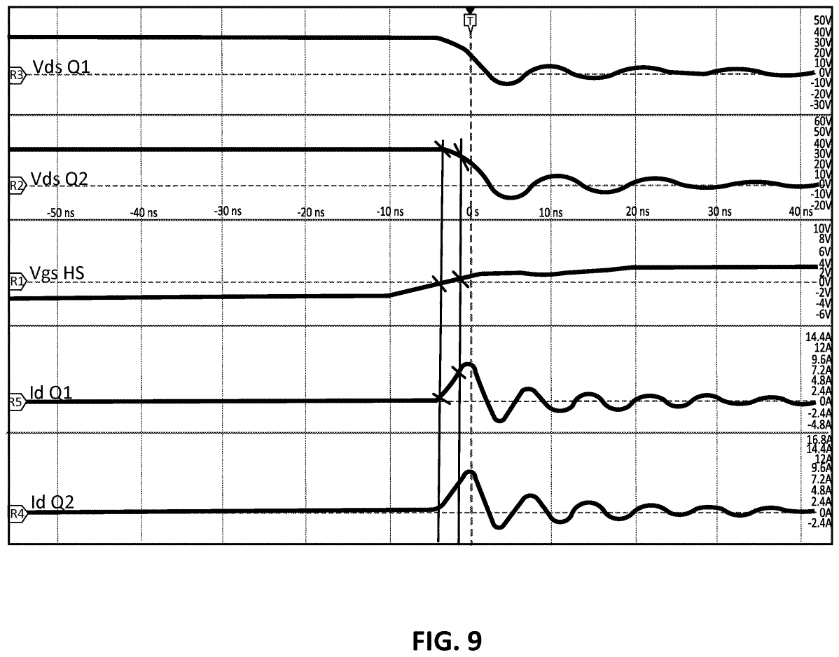

FIG. 9 shows a display of Vds and Id for the two MOSFETS and Vgs. The image shows a zoomed-in view, highlighted to show the region where Vgs starts to rise and Id just begins to increase, but before Vds has dropped significantly. To extract gm from switching waveforms, measurement algorithm will use a region where Vgs is actively rising meaning the device is turning on, Id is starting to rise as the channel is forming, Vds is relatively constant, ideally, at the beginning of the turn-on, before VDS falls sharply. The region is when Id starts to rise to before it reaches its peak

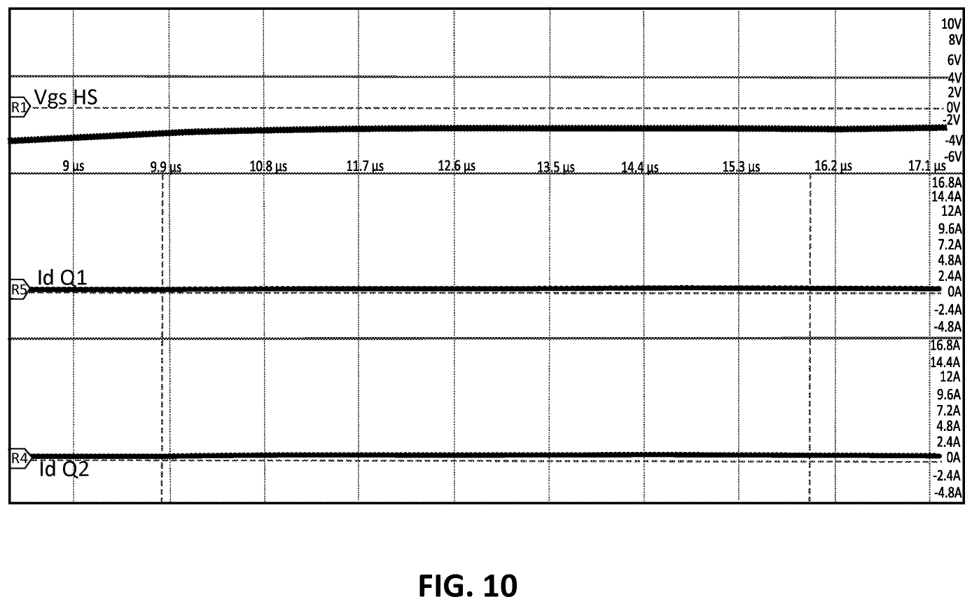

Another measurement involves leakage current, which is the small unwanted current that flows through a device even when it is supposed to be OFF. There is always some reverse bias leakage through the junction. The process for determining leakage current in a double-pulse test (DPT) involves a first pulse to turn device ON, and current builds, turn the device OFF, which blocks DC bus voltage. During the OFF time between pulses, the device is blocking high voltage. During this OFF-blocking period small current flows that is leakage current. FIG. 10 shows small leakage currents for Q1 and Q2.

Being able to determine inductance, allows monitoring of the parasitic inductance in each MOSFET's power path, critical for minimizing switching losses in parallel configurations. The process calculates the effective inductance (L_eff) for two parallel MOSFETs by analyzing their voltage and current waveforms during switching transitions. The fundamental inductance formula used is L_eff=V_mean/(dI/dt), where V_mean is the mean voltage across the load during the switching region, and dI/dt is the rate of change of current (slope). This comes from the inductor equation V=L×(dI/dt). To identify the slope, the instrument identifies turn-ON regions using gate edges, applies 20% buffers to focus on linear switching region, calculates current slope (dI/dt) for each MOSFET, measures mean voltage across each MOSFET and then computes the inductance using L=V/(dI/dt).

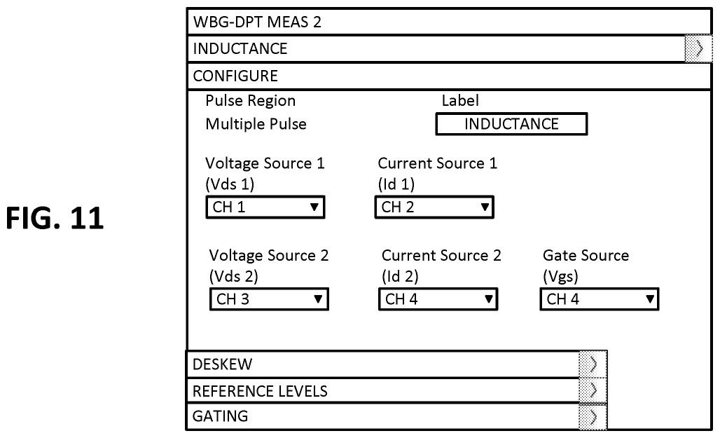

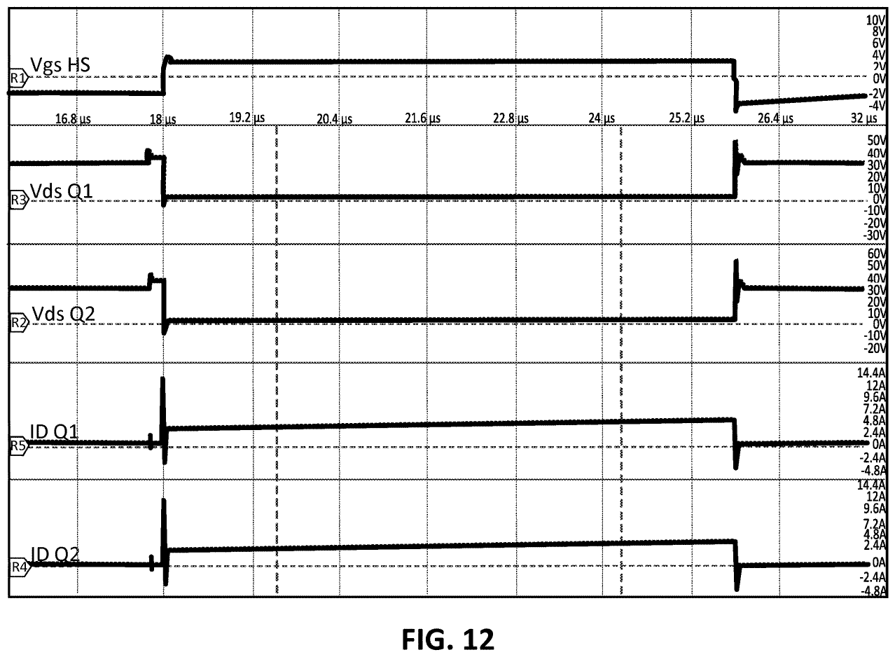

FIG. 11 shows an embodiment of a user interface allowing a user to set up an inductance test. FIG. 12 shows the resulting waveforms.

The damping factor is a dimensionless quantity that defines the nature of the transient response in parallel device switching waveforms. It explicitly measures the rate at which transient oscillations converge on the steady-state value, governing whether the system is underdamped, critically damped, or overdamped. The damping factor is calculated from the logarithmic decrement of consecutive oscillation peaks. One finds the logarithmic decrement by the formula:

$$Logarithmic Decrement : δ = ln \frac{( {Peak}_{1} - Steady {State}^{1} )}{( {Peak}_{2} - Steady {State}^{2} )} .$$

This is then used to find the damping factor:

$$Damping Factor : ζ = \frac{δ}{√ ( 4 {π}^{2} + {δ}^{2} )} ,$$

where Peak₁ is the first oscillation peak after the switching event, Peak₂ is the adjacent oscillation peak, Steady State is the mean value calculated over a specified time interval, Δt Peak 2 is the time difference between first two consecutive peaks in the second waveform.

The measurement is calculated between 20% before Vg rise edge to 30% after Vg rise edge in turn-on transient. The Steady State value is determined by analyzing the current signal within a specific On Region (20% to 80% after the Vg rise edge), after the initial switching transient has fully settled. A linear regression is performed on the data within this region, and the steady-state value is then calculated as the value of the fitted line by following equation: Steady State Value=slope×peak₁time+intercept.

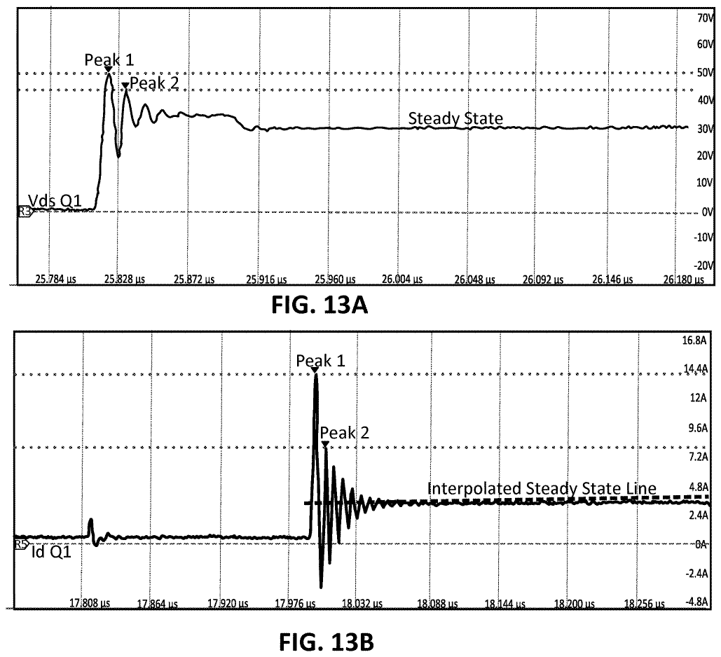

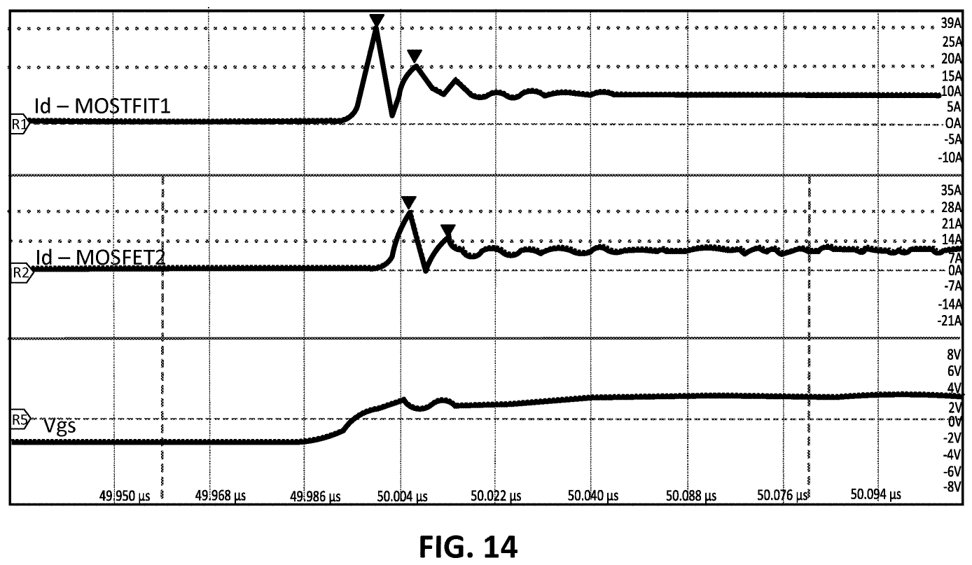

FIG. 13A shows overlapped waveforms for voltage showing the damping factor, and FIG. 13B shows overlapped waveforms for currents showing the damping factor. FIG. 14 shows an example of overlapped waveforms demonstrating the peaks in drain currents and the gate-source voltage showing the effects of a damping factor.

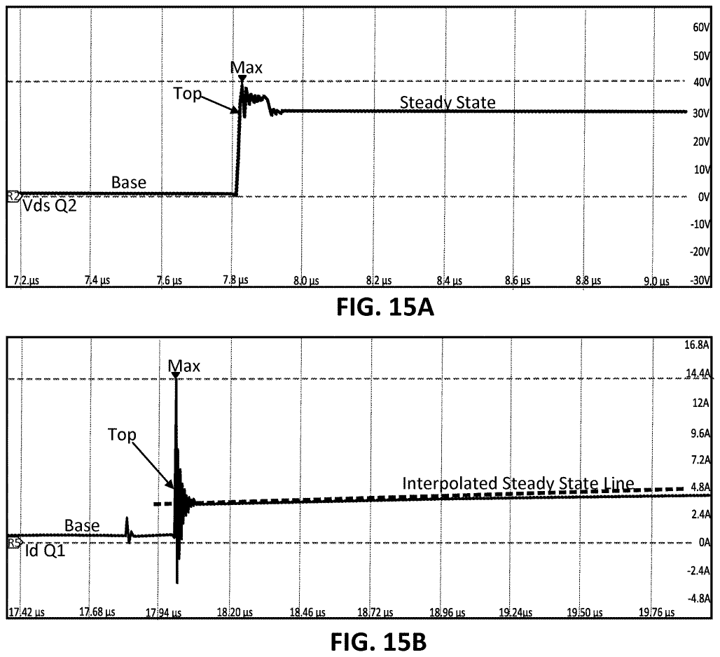

Overshoot is the maximum positive deviation of the waveform above its steady-state value during switching transients of power devices. The instrument can provide results that include Overshoot 1, Overshoot value for the first waveform, Overshoot 2, Overshoot value for the second waveform, and A Overshoot, which is absolute difference between the two overshoot values. The overshoot value will never be negative. FIG. 15 shows an embodiment of a user interface for overshoot, undershoot, and the damping factor.

The overshoot measurement is calculated between 20% before Vg fall edge to 80% after Vg fall edge during turn off transition. It is determined as a percentage, using the formula:

$$Overshoot \% = 100 \times \frac{( Max - Top )}{abs ( Top - Base )} ,$$

where the Top is an extrapolated value calculated on Id/Ic using linear regression between 20% to 80% after the Vg rise edge. The extrapolated value at the instant of current reaching maximum during device turn on is determined by top=slope*time of max+intercept. The Base is the mean current in the off region between 20% to 80% before the Vg rising edge. The steady-state value is determined by analyzing the current signal within a specific On Region (20% to 80% after the Vg rise edge), after the initial switching transient has fully settled. A linear regression is performed on the data within this region, and the steady-state value is then calculated as the value of the fitted line at the midpoint time of the chosen region. The steady state is determined by equation: Steady State=slope*time at center of current ramp+intercept

The instrument can also determine the Absolute Overshoot by subtracting the Steady State from the Max.

FIG. 15A shows overlapping waveforms showing overshoot for voltage, and FIG. 15B shows overlapped waveforms showing overshoot for current.

Undershoot is the maximum negative deviation of the waveform below its steady-state value during switching transients in parallel-connected power devices. It provides the results of Undershoot 1, the undershoot value for the first waveform, Undershoot 2, the Undershoot value for the second waveform, and A Undershoot, which is the absolute difference between the two undershoot values. The undershoot values should never be negative, unless Top or Base are set out-of-range. The undershoot measurement is calculated between 20% before Vg rise edge to 80% after Vg rise edge during turn on transition. It is determined by:

$$Undershoot percentage = \frac{Base - Min}{Amplitude} \times 100 \% .$$

The absolute measure is Undershoot=Steady State−Min. Where the steady-state value is calculated as the mean Vds/Vce voltage measured over the window starting 20% to 80% after the Vg rise edge during device turn on condition. The undershoot measurement is calculated between 20% before Vg fall edge to 80% after Vg fall edge during turn off transition. The Base/Steady State is the mean current in the off region after 20% to 80% after Vg fall edge. Top is an extrapolated value calculated on Id/Ic using linear regression between 20% to 80% before Vg fall edge. The extrapolated value at the instant of current reaching minimum during device turn off is determined by equation: top=slope*time of min+intercept.

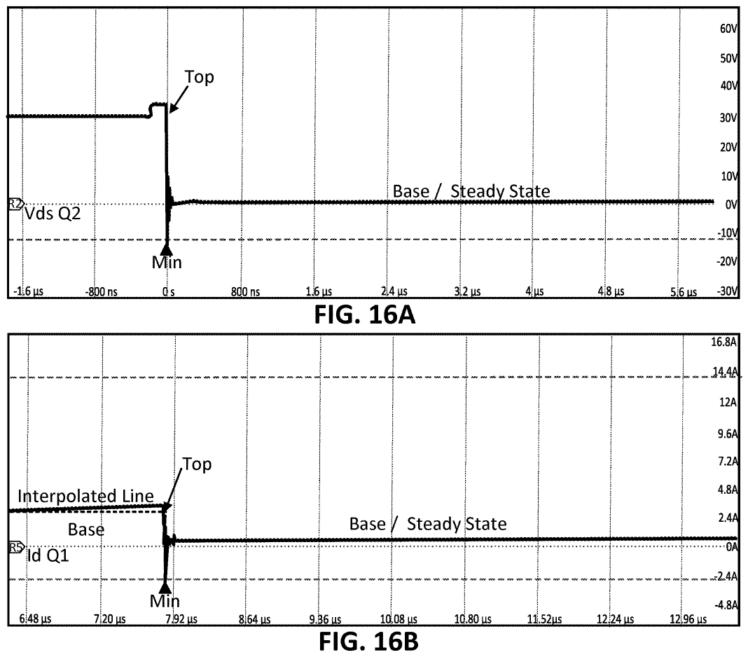

FIG. 16A shows overlapping waveforms showing undershoot for voltage, and FIG. 16B shows overlapped waveforms showing undershoot for current.

In this manner, one can monitor paralleled FETs to overcome issues and increase performance. The embodiments above provide overlapped current and voltage waveforms to allow detection of issues with current balancing, etc., and to provide solutions for adaptive management of operating parameters to correct the issues that arise in paralleled FETs.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement instrument, comprising: two or more probes, each probe configured to be coupled to one field effect transistor (FET) of at least two paralleled FETs operating on a device under test (DUT) to receive signals from a same test point on each of the FETs; one or more analog-to-digital converters (ADCs) to convert the signals to waveforms for each paralleled FET; a display; and one or more processors configured to execute code that causes the one or more processors to: display the waveform for each of the at least two paralleled FET as overlapping waveforms; measure one or more performance characteristics of the at least two paralleled FETs; and identify optimal operating parameters of the at least two paralleled FETs based upon the overlapping waveforms.

Example 2 is the test and measurement instrument of Example 1, wherein the code that causes the one or more processors to measure one or more performance characteristics of the at least two paralleled FETs comprises code that causes the one or more processors to measure and compare one or more of on-state current, dynamic on resistance, threshold gate-source voltage, transient current, overshoot, undershoot, switching loss, turn-on loss, turn-off loss, turn-on delay, turn-off delay, total current distortion, drain-source voltage, phase synchronization between the at least two paralleled FETs, body diode current, damping factor, leakage current, parasitic inductance, and transconductance.

Example 3 is the test and measurement instrument of either Examples 1 or 2, wherein the one or more processors are further configured to monitor the performance characteristics in real-time and detect fault conditions in the at least two or more paralleled FETs.

Example 4 is the test and measurement instrument of Example 3, wherein the code that causes the one or more processors to identify optimal operating parameters of the paralleled FETs comprises code that causes the one or more processors to identify optimal operating parameters based upon degradation of one or more of the paralleled FETs.

Example 5 is the test and measurement instrument of any of Examples 1 through 4, wherein the two or more probes comprise two or more wireless current sensors.

Example 6 is the test and measurement instrument of Example 5, wherein the two or more wireless current sensors are self-powered from current transients during switching transitions.

Example 7 is the test and measurement instrument of any of Examples 1 through 6, wherein the one or more processors are further configured to execute code that causes the one or more processors to operate an artificial-intelligence based gate drive tuning system that continuously adapts gate drive parameters based on performance characteristics of the at least two paralleled FETs.

Example 8 is the test and measurement instrument of Example 7, wherein the code that causes the one or more processors to operate the artificial-intelligence based gate drive tuning system comprises code that causes the artificial-intelligence based gate drive tuning system to align switching behaviors between the at least two paralleled FETs when the at least two paralleled FETs are of different compositions.

Example 9 is the test and measurement instrument of any of Examples 1 through 8, wherein the one or more processors are further configured to execute code to cause the one or more processors to receive thermal data from one or more thermal sensors on the DUT and identify optimal current sharing parameters based on different thermal conditions.

Example 10 is a method, comprising: receiving signals from at least two paralleled FETs on a device under test (DUT); converting the signals into waveforms for each paralleled FET; displaying the waveforms for each of the at least two paralleled FET as overlapping waveforms; measuring one or more performance characteristics of the at least two paralleled FETs; and identifying optimal operating parameters of the at least two paralleled FETs based upon the overlapping waveforms.

Example 11 is the method of Example 10, wherein measuring comprises measuring one or more of on-state current, dynamic on resistance, threshold gate-source voltage, transient current, overshoot, undershoot, witching loss, turn-on loss, turn-off loss, turn-on delay, turn-off delay, total current distortion, drain-source voltage, phase synchronization between the at least two paralleled FETs, body diode current, damping factor, leakage current, parasitic inductance, and transconductance.

Example 12 is the method of either Examples 10 or 11, further comprising monitoring the performance characteristics in real-time and detecting fault conditions in the at least two paralleled FETs.

Example 13 is the method of Example 12, wherein identifying optimal operating parameters of the paralleled FETs is based upon degradation of one or more of the paralleled FETs.

Example 14 is the method of any of Examples 10 through 13, wherein receiving signals from the at least two paralleled FETs comprises receiving signals from two or more probes.

Example 15 is the method of Example 14, wherein the two or more probes comprise two or more wireless current sensors.

Example 16 is the method of Example 15, wherein the two or more wireless current sensors are self-powered from current transients during switching transitions.

Example 17 is the method of any of Examples 10 through 16, further comprising operating an artificial-intelligence based gate drive tuning system that continuously adapts gate drive parameters based on performance characteristics of the at least two paralleled FETs.

Example 18 is the method of Example 17, wherein operating the artificial-intelligence based gate drive tuning system comprises aligning switching behaviors between the at least two paralleled FETs when the at least two paralleled FETs are of different compositions.

Example 19 is the method of any of Examples 10 through 18, further comprising receiving thermal data from one or more thermal sensors on the DUT and identifying optimal current sharing parameters based upon different thermal conditions.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
two or more probes, each probe configured to be coupled to one field effect transistor (FET) of at least two paralleled FETs operating on a device under test (DUT) to receive signals from a same test point on each of the FETs;
one or more analog-to-digital converters (ADCs) to convert the signals to waveforms for each paralleled FET;
a display; and
one or more processors configured to execute code that causes the one or more processors to:
display the waveform for each of the at least two paralleled FET as overlapping waveforms;
measure one or more performance characteristics of the at least two paralleled FETs; and
identify optimal operating parameters of the at least two paralleled FETs based upon the overlapping waveforms.

2. The test and measurement instrument as claimed in claim 1, wherein the code that causes the one or more processors to measure one or more performance characteristics of the at least two paralleled FETs comprises code that causes the one or more processors to measure and compare one or more of on-state current, dynamic on resistance, threshold gate-source voltage, transient current, overshoot, undershoot, switching loss, turn-on loss, turn-off loss, turn-on delay, turn-off delay, total current distortion, drain-source voltage, phase synchronization between the at least two paralleled FETs, body diode current, damping factor, leakage current, parasitic inductance, and transconductance.

3. The test and measurement instrument as claimed in claim 1, wherein the one or more processors are further configured to monitor the performance characteristics in real-time and detect fault conditions in the at least two or more paralleled FETs.

4. The test and measurement instrument as claimed in claim 3, wherein the code that causes the one or more processors to identify optimal operating parameters of the paralleled FETs comprises code that causes the one or more processors to identify optimal operating parameters based upon degradation of one or more of the paralleled FETs.

5. The test and measurement instrument as claimed in claim 1, wherein the two or more probes comprise two or more wireless current sensors.

6. The test and measurement instrument as claimed in claim 5, wherein the two or more wireless current sensors are self-powered from current transients during switching transitions.

7. The test and measurement instrument as claimed in claim 1, wherein the one or more processors are further configured to execute code that causes the one or more processors to operate an artificial-intelligence based gate drive tuning system that continuously adapts gate drive parameters based on performance characteristics of the at least two paralleled FETs.

8. The test and measurement instrument as claimed in claim 7, wherein the code that causes the one or more processors to operate the artificial-intelligence based gate drive tuning system comprises code that causes the artificial-intelligence based gate drive tuning system to align switching behaviors between the at least two paralleled FETs when the at least two paralleled FETs are of different compositions.

9. The test and measurement instrument as claimed in claim 1, wherein the one or more processors are further configured to execute code to cause the one or more processors to receive thermal data from one or more thermal sensors on the DUT and identify optimal current sharing parameters based on different thermal conditions.

10. A method, comprising:
receiving signals from at least two paralleled FETs on a device under test (DUT);
converting the signals into waveforms for each paralleled FET;
displaying the waveforms for each of the at least two paralleled FET as overlapping waveforms;
measuring one or more performance characteristics of the at least two paralleled FETs; and
identifying optimal operating parameters of the at least two paralleled FETs based upon the overlapping waveforms.

11. The method as claimed in claim 10, wherein measuring comprises measuring one or more of on-state current, dynamic on resistance, threshold gate-source voltage, transient current, overshoot, undershoot, witching loss, turn-on loss, turn-off loss, turn-on delay, turn-off delay, total current distortion, drain-source voltage, phase synchronization between the at least two paralleled FETs, body diode current, damping factor, leakage current, parasitic inductance, and transconductance.

12. The method as claimed in claim 10, further comprising monitoring the performance characteristics in real-time and detecting fault conditions in the at least two paralleled FETs.

13. The method as claimed in claim 12, wherein identifying optimal operating parameters of the paralleled FETs is based upon degradation of one or more of the paralleled FETs.

14. The method as claimed in claim 10, wherein receiving signals from the at least two paralleled FETs comprises receiving signals from two or more probes.

15. The method as claimed in claim 14, wherein the two or more probes comprise two or more wireless current sensors.

16. The method as claimed in claim 15, wherein the two or more wireless current sensors are self-powered from current transients during switching transitions.

17. The method as claimed in claim 10, further comprising operating an artificial-intelligence based gate drive tuning system that continuously adapts gate drive parameters based on performance characteristics of the at least two paralleled FETs.

18. The method as claimed in claim 17, wherein operating the artificial-intelligence based gate drive tuning system comprises aligning switching behaviors between the at least two paralleled FETs when the at least two paralleled FETs are of different compositions.

19. The method as claimed in claim 10, further comprising receiving thermal data from one or more thermal sensors on the DUT and identifying optimal current sharing parameters based upon different thermal conditions.
